(19) United States
(12) Patent Application Publication
(10) Pub. No.: US 2024/0413557 A1
(43) Pub. Date: Dec. 12, 2024

(54) DIRECT CONNECTION OF CONTACTORS AND SHUNT TO PRINTED CIRCUIT BOARD

(71) Applicant: Our Next Energy, Inc., Novi, MI (US)

(72) Inventors: Richard Hampo, Ann Arbor, MI (US); Shane Greenwood, Walled Lake, MI (US)

(21) Appl. No.: 18/737,045

(22) Filed: Jun. 7, 2024

Related U.S. Application Data
(60) Provisional application No. 63/506,824, filed on Jun. 7, 2023.

(51) Int. Cl. H01R 13/04; H01R 12/71; H05K 1/11

(52) U.S. Cl. CPC H01R 13/04; H01R 12/716; H05K 1/11; H05K 2201/10189; H05K 2201/10303

(57) ABSTRACT

Power distribution units, such as for electric vehicles, having reduced mass, volume and complexity are achieved with a power distribution circuit board having pin receptacles for receiving and electrically connecting with corresponding pins, and contactors having pins located in fixed proximity to the circuit board to facilitate an electrical connection between a connector pin and a corresponding pin receptacle on the circuit board.

### FIELD OF THE DISCLOSURE

This disclosure relates to power distribution units for safely distributing high voltage DC power using contactors controlled by a low voltage source, and more particularly to such units that have been configured to reduce mass and cost, while simplifying assembly.

### BACKGROUND OF THE DISCLOSURE

In conventional power distribution units, contactors and shunts are electrically connected with wire harnesses that have mass, volume and costs that would be desirable to reduce. Additionally, it would be desirable to simplify the structure and assembly process, and to reduce the potential for failure by using fewer and more reliable components and connections.

### SUMMARY OF THE DISCLOSURE

The disclosed power distribution units utilize direct connection of contactors and/or shunt to a printed circuit board to eliminate wire harnesses and thereby reducing space, mass and cost, while also simplifying assembly and providing more robust and reliable interfacing between contactors and control circuitry and/or between a shunt and the control circuitry. The power distribution units include a circuit board (e.g., a printed circuit board, PCB) that can have conductive traces electrically connecting electrical or electronic components to distribute power from one or more DC power sources to one or more DC loads, and one or more electrical (or electronic) components having connector pins. The circuit board includes pin receptacles for receiving and electrically connecting with a corresponding pin of an electrical (or electronic) component. The electrical component or electronic component is located in fixed proximity to the circuit board so that an electrical connection between a pin receptacle and corresponding pin is reliably made.

In certain embodiments, the power distribution unit includes one or more contactors that electrically interface with the circuit board via pins projecting from the contactors.

In certain other embodiments, the power distribution unit includes a shunt that electrically interfaces with the circuit board via pins projecting from the shunt.

In additional embodiments, the power distribution unit includes one or more contactors that are electrically interfaced with the circuit board via preferably pins and a shunt that electrically interfaces with the circuit board via projecting pins.

In any of the foregoing embodiments, the pin receptacles can be solder connected to the circuitry of the circuit board.

In any of the foregoing embodiments, the circuit board and the one or more electrical (or electronic) components can be fixed to and enclosed within a housing.

### BRIEF DESCRIPTION OF THE DRAWINGS

FIG. 1 is a schematic block diagram showing the electrical architecture of a power distribution unit.

FIG. 2 is an exploded perspective view of a power distribution unit in accordance with this disclosure.

FIG. 3 is an enlarged bottom view of a pin receptacle used in the power distribution unit of FIG. 2.

### DETAILED DESCRIPTION

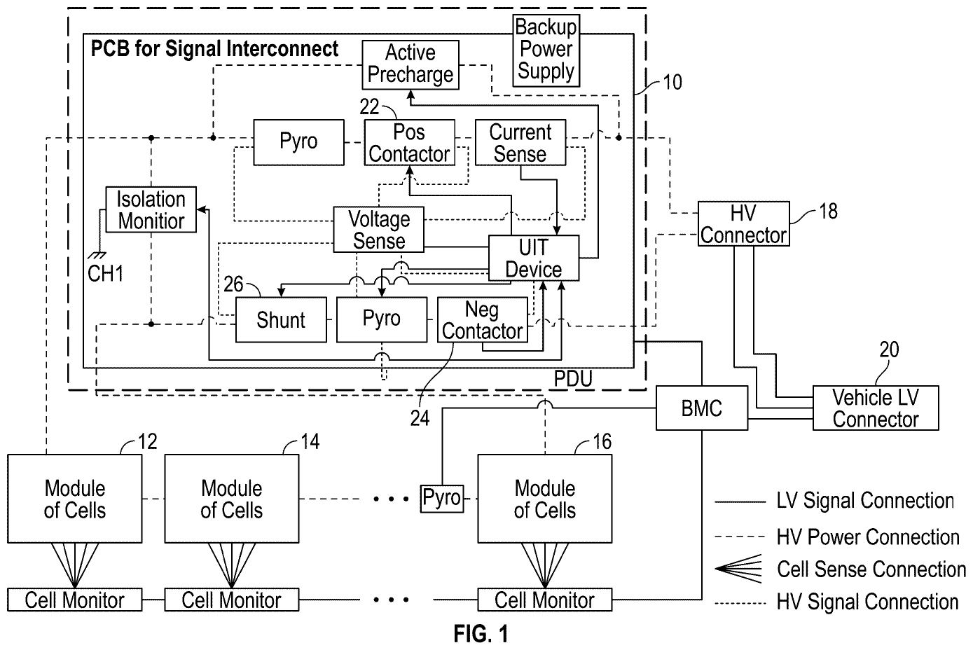

Shown schematically in FIG. 1 is a power distribution unit 10 for distributing DC power from a plurality of DC power sources 12, 14, 16 (e.g., batteries) to high voltage connector 18 and low voltage connector 20, which interface with DC loads. Unit 10 includes a positive contactor 22 and a negative contactor 24. Also included is a shunt 26, which is a low resistance path for measuring current and/or voltage. In a conventional power distribution unit, the contactors 22, 24 and shunt 26 do not interface directly with the circuit board, but instead interface via a wire harness.

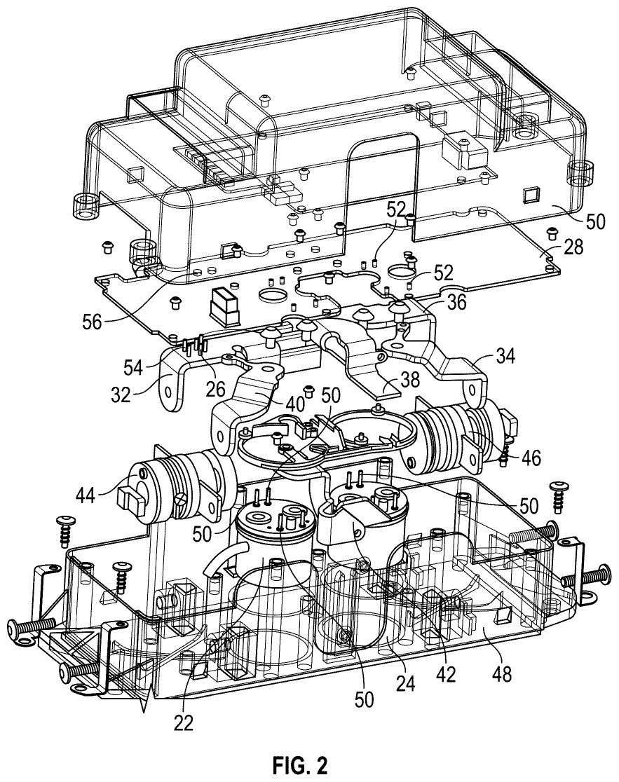

An exploded perspective of a power distribution unit 10 in accordance with the principals of this disclosure is shown in FIG. 2. Unit 10 includes a circuit board 28 configured to provide electrical connections among components that together control power distribution, contactors 22, 24, a shunt 26 integrated directly into busbar 32, various other busbars 34, 36, 38, 40 and 42 for electrical connections among various components, and pyro fuses 44, 46. The various components along with fasteners and retainers are affixed to and enclosed within a housing having a base 48 and a cover 49. As used herein, “electrical components,” such as contactors, shall be interpreted to include electronic components, such as diodes.

Rather than using wire harnesses to electrically connect contactors 22, 24 and shunt 26 with circuit board 28, contactors 22, 24 have projecting pins 50 that engage pin receptacles 52 soldered to circuit board 28, and shunt 26 has projecting pins 54 that engage pin receptacles 56 soldered to circuit board 28.

In certain embodiments, the pins 50 and 54 may be selectively deployable (extendable) and retractable.

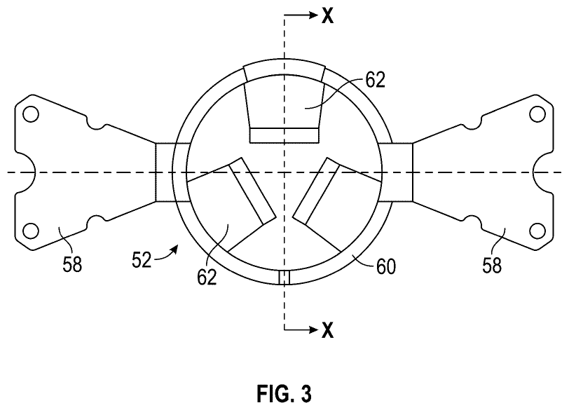

Shown in FIG. 3 is an enlarged bottom view of a pin receptacle 52 (or 56). The pin receptacles include outwardly projecting tabs 58 to facilitate attachment and electrical connection to circuit board 28, a cylindrical pin receiving section 60, and inwardly projecting resilient spring tabs 62 to achieve reliable electric contact with pins 50 (or 54) of contactors 22, 24 (or shunt 26), without requiring a solder connection between the pins and the PCB or the receptacles. The pin receiving section 60 of the receptacles extend at least partially through the thickness of the PCB, such that pins 50 and/or 54 extend into the depth (thickness) of the PCB.

While the present invention is described herein with reference to illustrated embodiments, it should be understood that the invention is not limited hereto. Those having ordinary skill in the art and access to the teachings herein will recognize additional modifications and embodiments within the scope thereof. Therefore, the present invention is limited only by the claims attached herein.

1. A power distribution unit, comprising:
a circuit board configured to distribute power from one or more DC power sources to one or more DC loads, the circuit board including pin receptacles for receiving and electrically connecting with a corresponding pin; and
one or more electrical components, each having conductive connector pins that project from the component, each electrical component being located in fixed proximity to the circuit board to facilitate an electrical connection between a connector pin and a corresponding pin receptacle soldered on the circuit board.

2. The unit of claim 1, wherein at least one of the one or more electrical components is a contactor.

3. The unit of claim 1, wherein at least two of the one or more electrical components are contactors.

4. The unit of claim 1, wherein at least one of the one or more electrical components is a shunt.

5. The unit of claim 1, wherein at least one of the one or more electrical components is a contactor, and at least one of the one or more electrical components is a shunt.

6. The unit of claim 1, wherein at least two of the one or more electrical components are contactors, and at least one of the one or more electrical components is a shunt.

7. The unit of claim 1, wherein the circuit board and the one or more electrical components are fixed to and enclosed by a housing.

8. The unit of claim 1, wherein the pins of at least one electrical component are selectively deployable and retractable.

9. The unit of claim 1, wherein each pin receptacle has a pin receiving section that extends at least partially through a thickness of the circuit board and a corresponding pin received in the pin receiving section extends into the depth of the circuit board.
